(19) United States
(12) Patent Application Publication
(10) Pub. No.: US 2019/0394402 A1
(43) Pub. Date: Dec. 26, 2019

(54) IMAGE SENSOR AND ELECTRONIC APPARATUS INCLUDING THE SAME

(71) Applicant: SAMSUNG ELECTRONICS CO., LTD., SUWON-SI (KR)

(72) Inventor: Byung Joon BAEK, INCHEON (KR)

(21) Appl. No.: 16/272,314

(22) Filed: Feb. 11, 2019

(30) Foreign Application Priority Data
Jun. 20, 2018 (KR) 10-2018-0070784

(51) Int. Cl. H04N 5/232; H04N 5/343

(52) U.S. Cl. CPC H04N 5/23293; H04N 5/23229; H04N 5/343; H04N 5/23245

(57) ABSTRACT

An image sensor includes a pixel array having a plurality of pixels and a logic circuit receiving a pixel signal from the plurality of pixels to generate image data. The logic circuit generates a preview image from the image data to output the preview image externally. An internal memory stores still images generated by the logic circuit from the image data. The logic circuit selects and outputs a result image corresponding to an event occurrence point of a capturing command from the still images stored in the internal memory, in response to the capturing command received from an external source.

### CROSS-REFERENCE TO RELATED APPLICATION(S)

This application claims benefit of priority to Korean Patent Application No. 10-2018-0070784 filed on Jun. 20, 2018 in the Korean Intellectual Property Office, the disclosure of which is incorporated herein by reference in its entirety.

### BACKGROUND

### 1. Field

The present disclosure relates to an image sensor and an electronic device including the same.

### 2. Description of Related Art

An image sensor, as a sensor generating an image by converting light coming from an external source into an electric signal, generates an image in response to a capturing command generated by a shutter operation of a user. Due to the movement of an object, an image of which a user desires to capture using an image sensor, a point in time at which a shutter operation of a user occurs and a point in time at which an image sensor generates an electrical signal in response to a capturing command may be different from each other. Recently, in order to significantly reduce a time difference between a point in time at which a shutter operation of a user occurs and a point in time at which an image sensor generates an electric signal, a zero shutter lag technique has been developed in various ways.

### SUMMARY

An aspect of the present disclosure is to provide an image sensor and an electronic device, including the same, capable of efficiently managing resource and power consumption of an image sensor and a bus, a processor, a memory, and the like, connected to the image sensor while implementing a function of zero shutter lag.

According to an embodiment of the present disclosure, an image sensor includes: a pixel array having a plurality of pixels; a logic circuit receiving a pixel signal from the plurality of pixels to generate image data, and generating a preview image from the image data to output the preview image externally; and an internal memory storing still images generated by the logic circuit from the image data. The logic circuit selects and outputs a result image corresponding to an event occurrence point of a capturing command from the still images stored in the internal memory, in response to the capturing command received from an external source.

According to an embodiment of the present disclosure, an electronic device includes: an image sensor generating still images and preview images, having a resolution lower than a resolution of the still images, and storing the still images in an internal memory; an input unit generating a capturing command; and a processor displaying a result image in response to the capturing command. The result image is one of the still images, corresponding to an event occurrence point at which the capturing command is generated.

According to an embodiment of the present disclosure, an image sensor includes: a first layer including a pixel array having a plurality of pixels; a second layer including a logic circuit that receives a pixel signal from the plurality of pixels, to generate still images, and adjusts a resolution of the still images to generate preview images, and disposed below the first layer; and a third layer including an internal memory storing the still images and disposed below the second layer.

According to an embodiment of the present disclosure, an electronic device includes an image sensor, an input device, a processor, and a memory. The image sensor generates images captured at different times. The input device generates a capture command in response to a shutter activation. The processor, in response to receiving the capture command, estimates a time when the shutter activation occurred. The memory stores the images and communicates to the processor a desired image, among the images, that is captured nearest the time when the shutter activation occurred.

### BRIEF DESCRIPTION OF DRAWINGS

The above and other aspects, features and other advantages of the present disclosure will be more clearly understood from the following detailed description, taken in conjunction with the accompanying drawings, in which:

FIG. 1 is a schematic block diagram illustrating an electronic device according to an example embodiment;

FIG. 2 illustrates a method of operating an image sensor according to related art;

FIG. 3 illustrates communication flow within an electronic device according to the related-art method illustrated by FIG. 2;

FIG. 4 illustrates a method of operating an image sensor according to an example embodiment;

FIG. 5 illustrates communication flow within an electronic device according to the method illustrated by FIG. 4, according to an example embodiment;

FIG. 6 illustrates a method of operating an image sensor according to another example embodiment;

FIG. 7 illustrates communication flow within an electronic device according to the method illustrated by FIG. 6, according to an example embodiment;

FIG. 8 illustrates communication flow within an electronic device according to the method illustrated by FIG. 6, according to another example embodiment;

FIG. 9 illustrates communication flow within an electronic device according to another example embodiment;

FIG. 10 illustrates communication flow within an electronic device according to yet another example embodiment;

FIG. 11 is a schematic perspective view illustrating an image sensor according to an example embodiment; and

FIG. 12 is a schematic perspective view illustrating an image sensor according to another example embodiment.

### DETAILED DESCRIPTION

Hereinafter, the exemplary embodiments of the present disclosure will be described in detail with reference to the attached drawings.

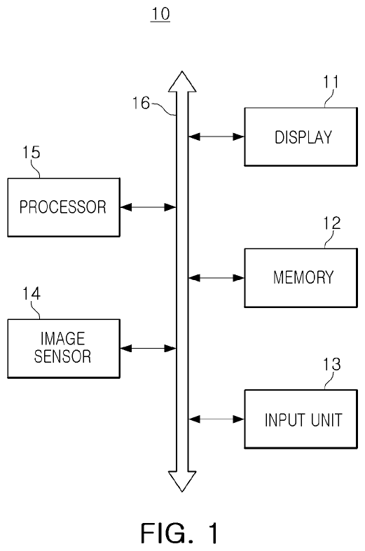

FIG. 1 is a schematic block diagram illustrating an electronic device according to an example embodiment.

Referring to FIG. 1, an electronic device 10 according to an example embodiment may include a display 11, a memory 12, an input unit 13, an image sensor 14, a processor 15, and the like. The electronic device 10 may include a television, a desktop computer, a monitor, and the like, in addition to mobile devices such as a smartphone, a tablet PC, a laptop computer, a digital camera, and the like. Components included in the electronic device 10, such as the display 11, the memory 12, the input unit 13, the image sensor 14, the processor 15, and the like may communicate with each other through a bus 16 to transfer data.

The image sensor 14 may include an internal memory storing data, in addition to a pixel array including a plurality of pixels and a logic circuit converting a charge, generated from the plurality of pixels, to an electrical signal to generate an image. For example, the internal memory may be provided as a single package together with the pixel array and the logic circuit.

When a camera function is executed using the image sensor 14, the logic circuit may generate a still image and a preview image using the electrical signal obtained from the plurality of pixels. For example, the preview image may be a preview screen provided to a user through the display 11 during the execution of the camera function and may have a size, and/or a resolution, smaller than that of the still image generated by capturing an image of an object by the image sensor 14.

In an example embodiment, to implement a function of zero shutter lag, an internal memory of the image sensor 14 or the memory 12 mounted on the electronic device 10 may be used. While the camera function is executed and the preview image is displayed on the display 11, the image sensor 14 may store the still images, generated according to a frame frequency, in an internal memory. Alternatively, the processor 15 may receive the still images from the image sensor 14 and store the still images in the memory 12.

When a shutter operation of a user occurs through the input unit 13, the occurrence time of the shutter operation is subsequently determined (e.g., calculated) by the image sensor 14 or the processor 15 so that at least one image, among the still images stored in the internal memory or in the memory 12, captured at the determined shutter-operation occurrence time may be displayed on the display 11 as a result image. The result image may be simultaneously displayed on the display 11 and stored in the memory 12. For example, there may be a time difference between a point in time at which a shutter operation of a user occurs and a point in time at which a capturing command is generated by the input unit 13 due to the shutter operation of a user. To solve a problem in which an accurate image at a point in time, which a user desires, cannot be obtained due to the time difference, in an example embodiment, the image sensor 14 stores still images in an internal memory or the memory 12 regardless of whether a capturing command is received. The occurrence time of a shutter operation is calculated when a capturing command is received and at least one, among the still images, is displayed on the display 11 as a result image and stored in the memory 12.

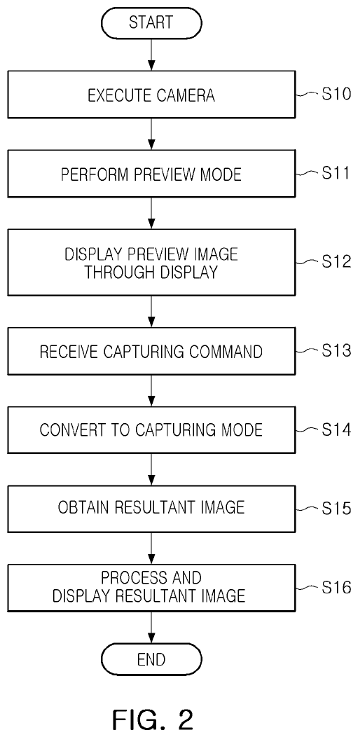

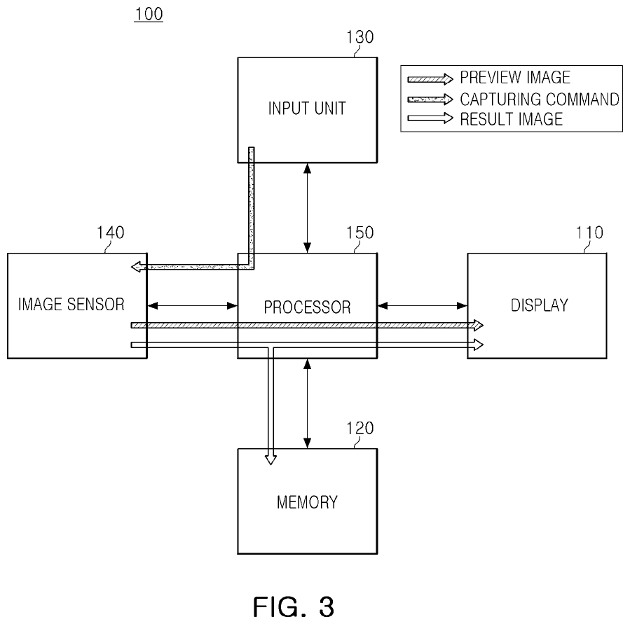

FIGS. 2 and 3 are drawings provided to describe an operation of an image sensor according to the related art.

First, referring to FIG. 2, when a camera function is executed in an electronic device 10 (S10), an image sensor 14 allows a preview mode to be executed (S11), while generating a preview image. The preview image may be displayed on a display 11 (S12). The preview image may refer to a preview image provided on a display 11, before a shutter operation for capturing a still image by an image sensor 14 is executed by a user.

After a shutter operation of a user or the like occurs, an image sensor 14 may receive a capturing command corresponding to the shutter operation (S13). A mode of the image sensor 14 is converted from a preview mode to a capturing mode (S14), a result image is obtained by capturing an image of an object (S15), an image processing process is applied to the result image, and the result image may be displayed on a display 11 (S16). The image processing process may include converting raw data, corresponding to a result image, to a predetermined image format, for example, a format such as JPG, BMP, PNG, or the like.

Here, the preview image and the result image may have different screen sizes and/or resolutions. For example, the still image may have a maximum size and resolution within a range which an image sensor 14 supports, while the preview image may have a size and a resolution that is smaller than the maximum size and resolution which the image sensor supports. For example, the image sensor 14 may generate a preview image by downscaling an image with a maximum size and resolution.

Thus, when a camera function is executed, a preview image is displayed through a display 11. When a capturing command is received, an image sensor 14 enters a capturing mode, thereby obtaining a result image. As a result, inevitably, there is a time difference between a point in time at which a shutter operation is executed by a user and a point in time at which a capturing command is received by an image sensor 14. Thus, a problem may occur, in which a result image, which a user desires, cannot be obtained depending on capturing conditions.

Referring to FIG. 3, an electronic device 100 may include a display 110, a memory 120, an input unit 130, an image sensor 140, a processor 150, and the like. When a camera function is executed, the image sensor 140 may generate a preview image to transmit the preview image to the processor 150 and the processor 150 may control the display 110 to display the preview image.

The input unit 130 may generate a capturing command corresponding to a shutter operation of a user to transmit the capturing command to the processor 150. When the processor 150 transmits the capturing command to the image sensor 140, the image sensor 140 may generate a result image at a point in time at which a capturing command is received and store the result image in the memory 120 while displaying the result image on the display 110. From a point in time at which a user executes a shutter operation a time elapses before the input unit 130 generates a capturing command that is transmitted to the image sensor 140 via the processor 150. The image sensor 140 generates a result image in response to the capturing command. Thus, the result image may be different from an image which a user desires.

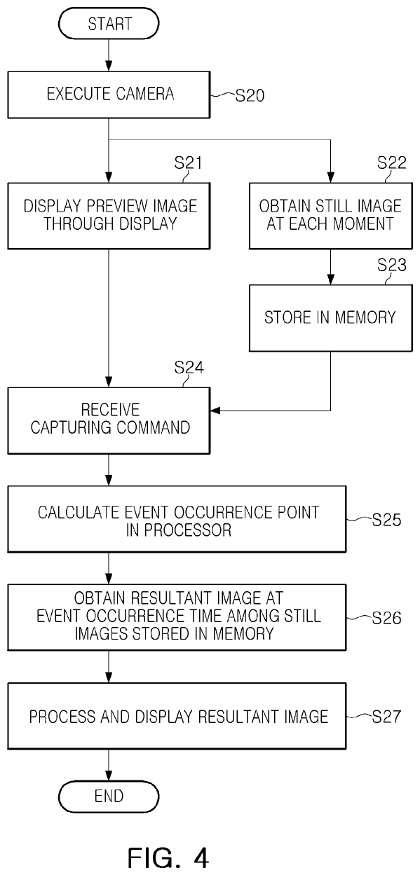

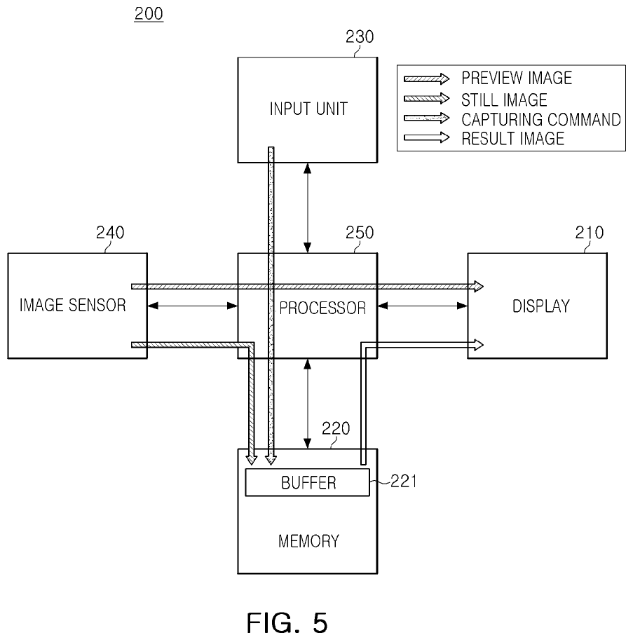

FIGS. 4 and 5 are drawings provided to describe an operation of an image sensor according to an example embodiment.

First, referring to FIG. 4, a camera function may be executed in an electronic device 100 (S20). When the camera function is executed, an image sensor 140 displays a preview image through a display 110 (S21), obtains still images at each of multiple successive moments (S22), and then stores the still images in the memory 120 (S23). For example, the image sensor 140 may obtain still images according to a preset frame frequency. A memory in which still images are stored may be a main memory 120 of the electronic device.

Then, when a shutter operation of a user, or the like, occurs and a processor 150 subsequently receives a capturing command (S24), the processor 150 may calculate an estimated event occurrence point at which the shutter operation occurred using a point in time at which the capturing command is received, a data transmission speed between the input unit 130 and the processor 150, and the like (S25). The processor 150 may obtain, as a result image, a still image generated by the image sensor 140 at the estimated event occurrence point or a point in time closest to the estimated event occurrence point, among the still images stored in the memory 120 (S26). The processor 150 may allow the result image to be image-processed and may display the result image on the display 110 (S27).

When there is no still image generated by the image sensor 140 at a point in time consistent with the event occurrence point, the processor 150 may withdraw from the memory 120 all still images generated by the image sensor 140 within a predetermined time range of the event occurrence point and may display the still images on the display 110. A user may select at least one from the still images displayed on the display 110, and the processor 150 may store the still image, selected by the user, in the memory 120 as a result image.

FIG. 5 is a drawing provided to describe the flow of data according to the method described with reference to FIG. 4. An electronic device 200 may include a display 210, a memory 220, an input unit 230, an image sensor 240, a processor 250, and the like.

First, when a camera function is executed, the image sensor 240 may generate a preview image to transmit to the processor 250, and the processor 250 may control the display 210 to display the preview image. Simultaneously, the image sensor 240 may generate still images and store the still images in a buffer 221 of the memory 220. For example, the buffer 221 may be a ring buffer, operated in a first-in-first-out (FIFO) manner. In other words, the processor 250 may delete an earliest-saved still image and may store a latest-created still image, when a storage space of the buffer 221 is full due to the still images transmitted by the image sensor 240.

When the input unit 230 generates a capturing command in response to a shutter operation of a user, the processor 250 may select at least one of the still images stored in the buffer 221, as a result image in response to the capturing command. For example, the processor 250 may receive the capturing command and then may calculate an estimated event occurrence point at which a shutter operation of a user occurred. The processor 250: (1) withdraws, as a result image, a still image stored in the buffer 221 and generated by the image sensor 240 at an event occurrence point or a point in time closest to the event occurrence point, (2) displays the result image on the display 210, and (3) stores the result image in the memory 220. For example, the result image may be stored in an area in the memory 220, rather than the buffer 221.

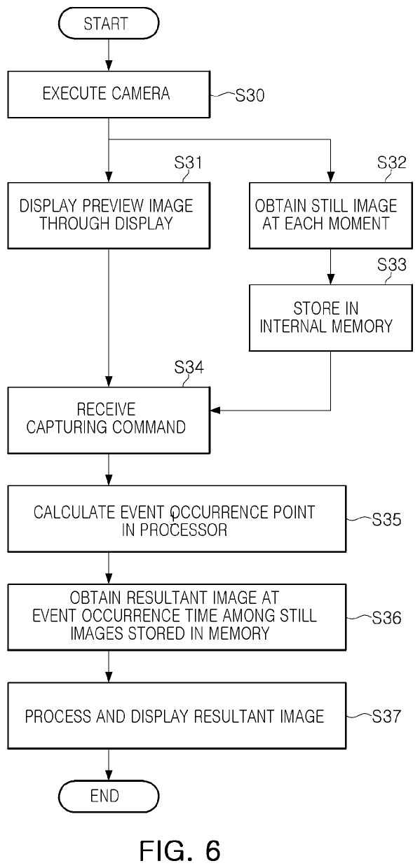

FIGS. 6 to 8 are drawings provided to describe an operation of an image sensor according to an example embodiment.

First, referring to FIG. 6, an operation of an image sensor 240 according to an example embodiment may be started by executing a camera function in an electronic device 200 with an image sensor 240 mounted therein (S30). When the camera function is executed, the image sensor 240 displays a preview image through a display 210 (S31) and obtains still images at each of multiple successive moments (S32) that are stored in an internal memory of the image sensor 240, rather than a system memory 220 (S33). The internal memory may be a memory provided as a single package with the image sensor.

Then, after a shutter operation of a user, or the like, occurs, the processor 250 receives a capturing command, corresponding to the shutter operation (S34), and may calculate an event occurrence point with respect to the capturing command (S35). For example, the event occurrence point may correspond to a point in time at which a shutter operation of a user occurred and may occur before a point in time at which a capturing command is received. Thus, the processor 250 may calculate an estimated time of the event occurrence point or how long before the capturing command is received that the event occurrence point is estimated to have occurred. The processor 250 may deliver the event occurrence point (e.g., time) to the image sensor 240 and the image sensor 240 may obtain a still image corresponding to the event occurrence point, among the still images stored in an internal memory, as a result image (S36). The image sensor 240 may deliver a result image to a processor 250 and the processor 250 may display the result image on the display 210 (S37). According to example embodiments, an image processing process with respect to a result image may be executed in the image sensor 240 or the processor 250.

Moreover, in a manner different from that described above according to an example embodiment, the image sensor 240 may directly receive a capturing command from an input unit 230. In other words, the capturing command, generated in response to a shutter operation of a user by the input unit 230, may be delivered to an image sensor not through a processor 250. The image sensor 240 may calculate an event occurrence point from a capturing command using internal firmware, or the like, and may select a still image, captured at the event occurrence point or a point in time closest to the event occurrence point, as a result image and withdraw the still image from an internal memory. In this case, the capturing command may be delivered to the image sensor 240 directly, not through the processor 250, so an internal resource of the electronic device 200 may be operated more efficiently.

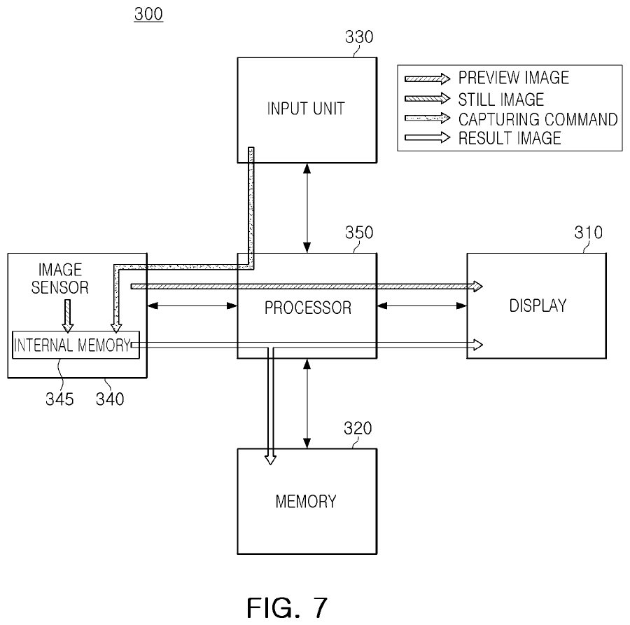

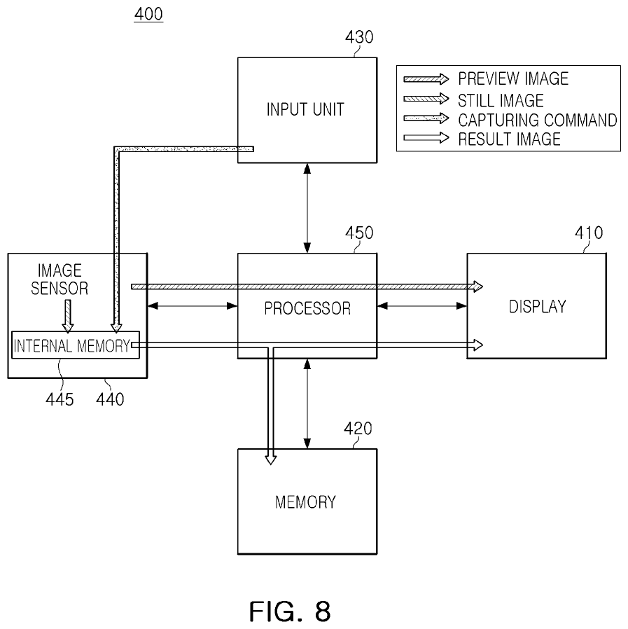

FIGS. 7 and 8 are drawings provided to describe the flow of data according to the method described with reference to FIG. 6.

First, referring to FIG. 7, after a camera function is executed in an electronic device 300, an image sensor 340 may generate a preview image. The preview image may be displayed on a display 310 by a processor 350. Moreover, the image sensor 340 may generate still images and store the still images in an internal memory 345 of the image sensor 340. The still images may be generated according to a predetermined frame frequency, or the like, and the preview image may be generated by downscaling the still images. The internal memory 345 may be a memory provided as a single package with the image sensor 340. Thus, as compared with a case in which still images are stored in the memory 320 through the processor 350, a resource of a bus connecting the memory 320, the image sensor 340, and the processor 350, may be efficiently operated.

When a shutter operation of a user is detected during execution of a camera function, the input unit 330 may generate and output a capturing command. The processor 350 may receive a capturing command output by the input unit 330 and may calculate an event occurrence point, which is estimated as a point in time at which a user executed a shutter operation, in consideration of a point in time at which a capturing command is received, a data transmission speed of a system bus connecting the processor 350 to the input unit 330, and the like. The processor 350 may transmit an event occurrence point to the image sensor 340, and the image sensor 340 may withdraw a still image, corresponding to the event occurrence point or a point in time closest to the event occurrence point, from the internal memory 345 as a result image. The image sensor 340 may output the result image, and the processor 350 may display the result image on the display 310 while storing the result image in the memory 320.

Next, referring to FIG. 8, after a camera function is executed within an electronic device 400, an image sensor 440 may generate a preview image and the preview image may be displayed on a display 410 by a processor 450. Moreover, the image sensor 440 may generate still images according to a predetermined frame frequency, or the like, and may store the still images in an internal memory 445. In an example embodiment, the preview image may be generated by downscaling the still images. The internal memory 445 may be a memory provided as a single package with the image sensor 440. Thus, as compared with a case in which still images are stored in the memory 420 through the processor 450, resources of a bus and an interconnection line connecting the memory 420, the image sensor 440, and the processor 450 may be efficiently operated.

For example, assuming that the image sensor 440 has a sensor array for 24 mega-pixels and is operated at a frame frequency of 30 frames-per-second (fps) and a single pixel is represented by 10 bit image data, an amount of data per unit time transmitted to the memory 420 through the bus and the processor 450 in one second may be 7.2 giga-bits per second (Gbps). On the other hand, according to an example embodiment illustrated in FIG. 8, still images are stored in an internal memory 445 of an image sensor 440 and are not stored in a memory 420 through a bus and a processor 450, so that a data transmission amount may be reduced. Only in an operation in which a capturing command is received by the image sensor 440 and a result image is selected from the internal memory 445 and delivered to the display 410 is data transmission through a bus and a processor 450 executed. Thus, a data transmission amount is reduced, so a bus, which is a limited resource, may be effectively managed and power consumption of the electronic device 400 may be reduced. The example described above may be similarly applied to the example embodiment described with reference to FIG. 7.

In an example embodiment illustrated in FIG. 8, a capturing command, generated by an input unit 430 by detecting a shutter operation of a user, may be directly input to an image sensor 440, rather than through a processor 450. The image sensor 440 may receive a capturing command from the input unit 430 through a serial packet interface (SPI) and/or an I2C interface, or the like. The firmware, installed in the image sensor 440, or the like, may calculate an assumed event occurrence point, at which a shutter operation of a user occurred, based on a point in time at which a capturing command is received. The image sensor 440 may select, as a result image, a still image corresponding to an event occurrence point or corresponding to a point in time closest to the event occurrence point, among the still images stored in an internal memory 445, and may transfer the result image to the processor 450. The processor 450 may store the result image in the memory 420 and may display the result image on the display 410.

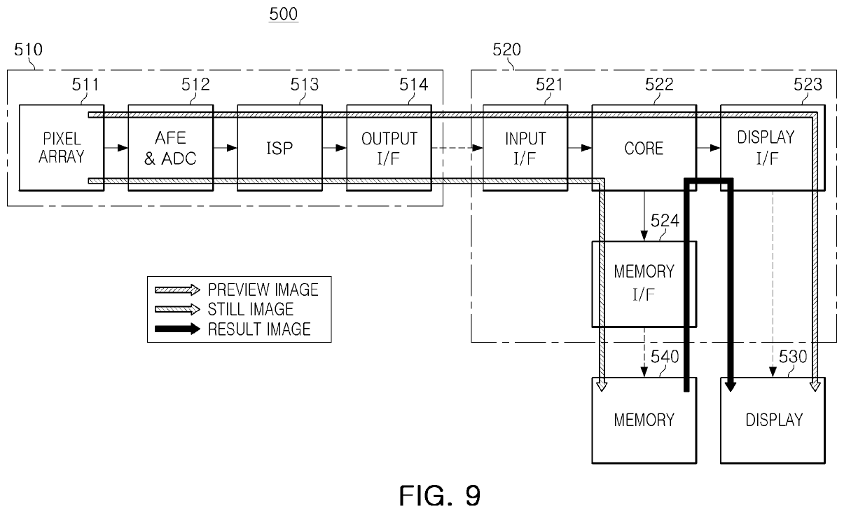

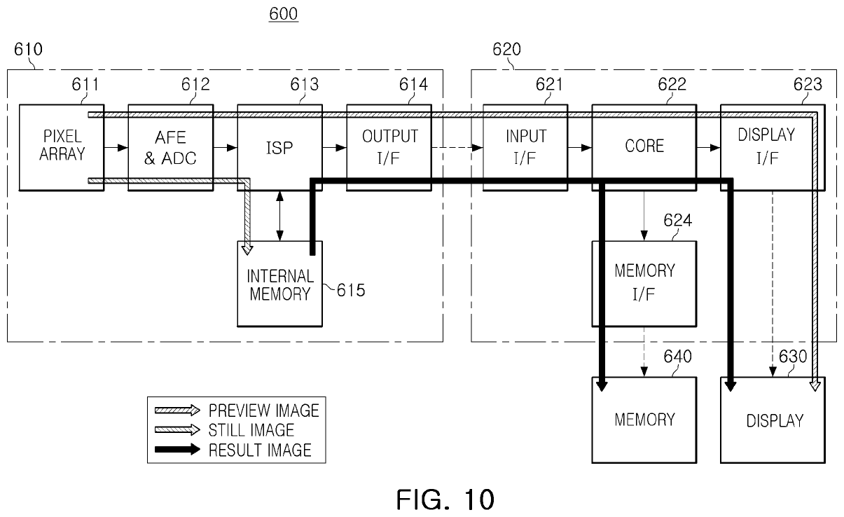

FIGS. 9 and 10 are drawings provided to describe an operation of an electronic device according to an example embodiment.

First, referring to FIG. 9, an electronic device 500 may include an image sensor 510, a processor 520, a display 530, a memory 540, and the like. The image sensor 510 may include a pixel array 511, an analog-front-end module 512, an image processing module 513 (e.g., an image signal processing (ISP) module), an output interface 514, and the like. When a camera function is executed in the electronic device 500, the analog-front-end module 512 may obtain a pixel signal from the pixel array 511 and then convert the pixel signal to a digital signal and transmit the digital signal to the image processing module 513. The analog-front-end module 512 may include a sampling circuit for obtaining a pixel signal, an analog-digital converter (ADC) for converting a pixel signal to a digital signal, and the like.

The image processing module 513 may generate an image using a digital signal and may output the image through the output interface 514. For example, the image processing module 513 may generate a still image having a maximum resolution, provided from pixels included in the pixel array 511, and a preview image generated by downscaling the still image. The output interface 514 is connected to an input interface 521 of the processor 520 through a MIPI interface, or the like, and may transmit a still image and a preview image to the processor 520.

The processor 520 may include an input interface 521, a core 522, a display interface 523, a memory interface 524, and the like. The core 522 may be a component capable of performing various calculation functions. The core 522 may output the preview image, received through the input interface 521, on the display 530 through the display interface 523. The display 530 may display the preview image.

Meanwhile, the core 522 may store the still images, received through the image sensor 510, in the memory 540 through the memory interface 524. The image sensor 510 may generate a plurality of still images according to a predetermined frame frequency, and the core 522 may store the still images in the memory 520.

When a capturing command is generated by a shutter operation of a user, or the like, the core 522 may calculate an event occurrence point corresponding to a point in time at which a shutter operation occurred, rather than a point in time at which a capturing command is received. For example, the point in time at which a shutter operation occurs may be earlier than the point in time at which a capturing command is received. The core 522 may select and withdraw a still image, corresponding to an event occurrence point, as a result image from the memory 540 and may display the result image on the display 530. Moreover, the result image may be stored in an area of the memory 540, separate from an area in which other still images are stored.

Next, referring to FIG. 10, an electronic device 600 may include an image sensor 610, a processor 620, a display 630, a memory 640, and the like. The image sensor 610 may include a pixel array 611, an analog-front-end module 612, an image processing module 613, an output interface 614, an internal memory 615, and the like. The processor 620 may include an input interface 621, a core 622, a display interface 623, a memory interface 624, and the like. The core 622 may be a component capable of performing various calculation functions. The core 622 may output the preview image, received through the input interface 621, on the display 630 through the display interface 623. The display 630 may display the preview image. The core 622 may store the still images, received through the image sensor 610, in the memory 640 through the memory interface 624.

When a camera function is executed, the analog-front-end module 612 may obtain a pixel signal from the pixel array 611 and then convert the pixel signal to a digital signal and transmit the digital signal to the image processing module 613. The image processing module 613 may generate an image using a digital signal.

As described previously, the image processing module 613 may generate still images corresponding to a maximum resolution, which is able to be provided by pixels included in the pixel array 611, according to a predetermined frame frequency. Moreover, the image processing module 613 may generate a preview image by downscaling still images. The image processing module 613 may output a preview image to the processor 620 through the output interface 614 and may store the still images in the internal memory 615. Thus, as compared with the example embodiment illustrated in FIG. 9, operations for transmitting still images by an interconnection line and a bus between the image sensor 610 and the processor 620 and storing still images in the memory 640 through an interconnection line and a bus between the processor 620 and the memory 640 may be omitted. As a result, a data transmission amount through an interconnection line and a bus is reduced, so a limited resource may be efficiently managed and power consumption may be reduced.

The processor 620 may display the preview image, received through the input interface 621, on the display 630. When a shutter operation of a user is detected, the processor 620 may select at least one, among still images stored in the internal memory 615 of the image sensor 610, as a result image, store the result image in the memory 640, and display the result image on the display 630. In a manner similar to the example embodiment described with reference to FIG. 9, the result image may be a still image generated by the image sensor 610 at a point in time at which a shutter operation of a user occurs.

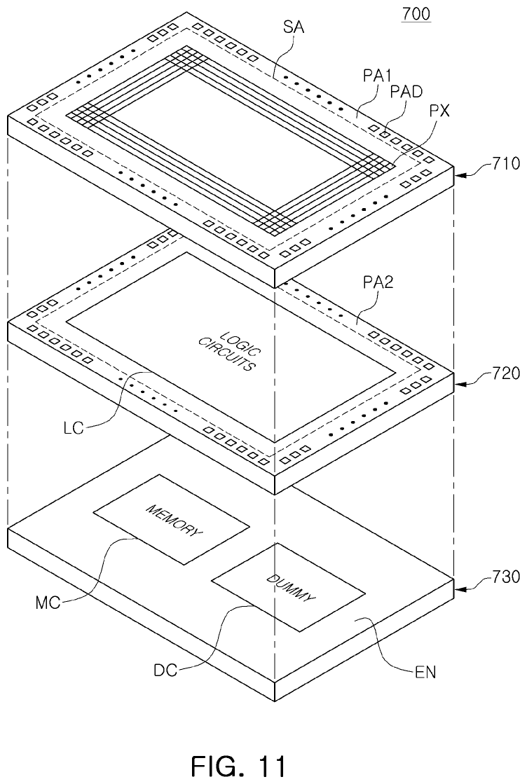

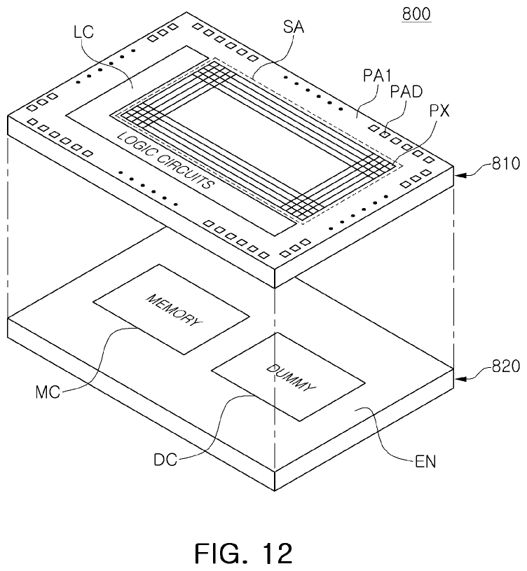

FIGS. 11 and 12 are schematic perspective views illustrating an image sensor according to an example embodiment.

First, referring to FIG. 11, an image sensor 700 according to an example embodiment may include a first layer 710, a second layer 720 provided below the first layer 710, a third layer 730 provided below the second layer 720, and the like. The first layer 710, the second layer 720, and the third layer 730 are stacked in a vertical direction. In an example embodiment, the first layer 710 and the second layer 720 are stacked at a wafer level and the third layer 730 may be attached to a lower portion of the second layer 720 at a chip level. The first layer 710, the second layer 720, and the third layer 730 may be provided as a single semiconductor package.

The first layer 710 may include a sensing area SA, having a plurality of pixels PX provided therein, and a first pad area PA1 provided around the sensing area SA. The first pad area PA1 includes a plurality of upper pads PAD, and the plurality of upper pads PAD may be connected to pads, provided in a second pad area PA2 of the second layer 720, and a logic circuit LC through a via, or the like.

Each of the plurality of pixels PX may include: (1) a photoelectric device receiving light and generating a charge, (2) a pixel circuit converting the charge generated by the photoelectric device to an electrical signal, and (3) the like. The photoelectric device may include an organic photodiode, a semiconductor photodiode, or the like. In an example embodiment, the plurality of semiconductor photodiodes may be included in each of the plurality of pixels PX. The pixel circuit may include a plurality of transistors for converting the charge, generated by the photoelectric device, to an electrical signal.

The second layer 720 may include a plurality of circuit elements formed in the logic circuit LC. The plurality of circuit elements, included in the logic circuit LC, may provide circuits for driving a pixel circuit provided in the first layer 710, for example, a row driver, a column driver, a timing controller, and the like. The plurality of circuit elements, included in the logic circuit LC, may be connected to a pixel circuit through the first pad area PA1 and the second pad area PA2.

The third layer 730, provided below the second layer 720, may include a memory chip MC and a dummy chip DC, and a protective layer EN sealing the memory chip MC and the dummy chip DC. The memory chip MC may be a dynamic random access memory (DRAM) or a static random access memory (SRAM), and the dummy chip DC may not have a function for storing data. The memory chip MC may be electrically connected to at least a portion of circuit elements included in the logic circuit LC of the second layer 720 by a bump. In an example embodiment, the bump may be a micro bump.

In example embodiments, still images, generated by the logic circuit LC, may be stored in the memory chip MC of the third layer 730. Thus, still images having a resolution and capacity, relatively larger than those of a preview image, are generated according to a frame frequency and may not be transmitted to an outside of the image sensor 700. As a result, the still images are stored in the memory chip MC through an interconnection line between the logic circuit LC and the memory chip MC in the image sensor 700, so a limited resource in an electronic device including the image sensor 700 may be efficiently operated while power consumption is reduced.

Next, referring to FIG. 12, an image sensor 800 according to an example embodiment may include a first layer 810 and a second layer 820. The first layer 810 may include a sensing area SA having a plurality of pixels PX provided therein, a logic circuit area LC having circuit elements for driving the plurality of pixels PX, and a first pad area PA1 provided around the sensing area SA and the logic circuit area LC. The first pad area PA1 includes a plurality of upper pads PAD, and the plurality of upper pads PAD may be connected to a memory chip MC provided in the second layer 820 through a via, or the like. The second layer 820 may include a memory chip MC, a dummy chip DC, and a protective layer EN sealing the memory chip MC and the dummy chip DC.

In an example embodiment illustrated in FIG. 12, after a camera function is executed, the logic circuit LC may generate still images for each predetermined frame frequency and may store the still images in the memory chip MC. Moreover, the logic circuit LC may generate and output a preview image obtained by reducing a resolution and/or a size of still images. Only the preview image, occupying a relatively small data transmission amount, is output externally of the image sensor 800, and the still images are stored in an internal memory chip MC. Thus, a data transmission amount may be reduced. Meanwhile, while a capturing command is received, the image sensor 800 may select a still image, corresponding to a point in time at which a shutter operation of a user occurred, from the memory chip MC and output the still image as a result image, without a process of generating a separate still image in a capturing mode. Thus, a function of zero shutter lag may be implemented.

As set forth above, according to example embodiments of the present disclosure, a function of zero shutter lag may be implemented in an image sensor. An image sensor and a resource such as a processor, a bus, a memory, and the like, connected to the image sensor may be efficiently managed, and power consumption of an image sensor and an electronic device including the same may be reduced.

As is traditional in the field, embodiments may be described and illustrated in terms of blocks which carry out a described function or functions. These blocks, which may be referred to herein as units or modules or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by firmware and/or software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While example embodiments have been shown and described above, it will be apparent to those skilled in the art that modifications and variations could be made without departing from the scope of the present disclosure, as defined by the appended claims.

1. An image sensor comprising:
a pixel array having a plurality of pixels;
a logic circuit that receives a pixel signal from the plurality of pixels to generate image data and generates a preview image from the image data to output the preview image externally; and
an internal memory that stores still images generated by the logic circuit from the image data, wherein
the logic circuit selects and outputs a result image, corresponding to an event occurrence point of a capturing command, from the still images stored in the internal memory, in response to the capturing command received from an external source.

2. The image sensor of claim 1, wherein the preview image has a resolution smaller than a resolution of the still images.

3. The image sensor of claim 1, wherein the logic circuit generates the still images from the image data and generates the preview image by downscaling the still images.

4. The image sensor of claim 1, wherein the logic circuit includes:
a sampling circuit that receives the pixel signal from the plurality of pixels;
an analog-digital converter (ADC) that converts the pixel signal to the image data; and
an image signal processor (ISP) that generates the still images and the preview image using the image data.

5. The image sensor of claim 1, wherein:
the logic circuit includes an interface circuit that receives the capturing command and transmits the preview image and the result image, and
the interface circuit directly receives the capturing command from an input device.

6. The image sensor of claim 1, wherein the internal memory includes a buffer that stores the still images.

7. The image sensor of claim 6, wherein the buffer stores the still images by operating in a first-in-first-out (FIFO) manner.

8. The image sensor of claim 6, wherein the logic circuit deletes a still image, which is first stored, among the still images, and stores a new still image, when a storage space of the buffer is full.

9. The image sensor of claim 1, wherein the pixel array, the logic circuit, and the internal memory are included in a single semiconductor package and the internal memory is disposed below the pixel array and the logic circuit.

10. The image sensor of claim 9, further comprising a dummy memory disposed at a same level as that of the internal memory.

11. The image sensor of claim 1, wherein the logic circuit generates the still images from the image data according to a predetermined frame frequency and stores the still images in the internal memory.

12. An electronic device comprising:
an image sensor that generates still images and preview images having a resolution lower than a resolution of the still images and stores the still images in an internal memory;
an input device that generates a capturing command; and
a processor that displays, on a display, a result image in response to the capturing command, wherein
the result image is one of the still images corresponding to an event occurrence point at which the capturing command is generated.

13. The electronic device of claim 12, wherein:
the processor determines the event occurrence point from the capturing command and transmits the event occurrence point to the image sensor, and
the image sensor selects the result image from the still images and transmits the result image to the processor.

14. The electronic device of claim 12, wherein the image sensor directly receives the capturing command from the input device, determines the event occurrence point, selects the result image from the still images, and transmits the result image to the processor.

15. The electronic device of claim 12, wherein the processor stores the result image in a memory different from the internal memory.

16. The electronic device of claim 12, wherein the processor displays the preview images on the display, before the capturing command is generated.

17. The electronic device of claim 12, wherein the input device includes:
a touch screen provided integrally with the display, and
a touch controller that generates the capturing command from a touch input to the touch screen.

18. An image sensor comprising:
a first layer including a pixel array having a plurality of pixels;
a second layer including a logic circuit that receives a pixel signal from the plurality of pixels to generate still images and adjusts a resolution of the still images to generate preview images, wherein the second layer is disposed below the first layer; and
a third layer including an internal memory that stores the still images and is disposed below the second layer.

19. The image sensor of claim 18, wherein the third layer further includes:
a dummy memory provided as a semiconductor die different from the internal memory, and
an encapsulant fixing the internal memory and the dummy memory.

20. The image sensor of claim 18, wherein the first layer, the second layer, and the third layer are provided as a single semiconductor package.

21-29. (canceled)
